(19) United States
(12) Patent Application Publication
(10) Pub. No.: US 2015/0187656 A1
(43) Pub. Date: Jul. 2, 2015

(54) LASER ANNEALS FOR REDUCED DIODE LEAKAGE

(71) Applicant: Texas Instruments Incorporated, Dallas, TX (US)

(72) Inventors: Younsung CHOI, Plano, TX (US); Kwan-Yong LIM, Plano, TX (US); Ebenezer ESHUN, Plano, TX (US)

(21) Appl. No.: 14/576,769

(22) Filed: Dec. 19, 2014

Related U.S. Application Data
(60) Provisional application No. 61/921,508, filed on Dec. 29, 2013.

(51) Int. Cl. H01L 21/8234; H01L 21/02; H01L 21/265; H01L 29/78; H01L 21/324; H01L 21/268

(52) U.S. Cl. CPC H01L 21/823437; H01L 21/324; H01L 21/268; H01L 21/265; H01L 29/7847; H01L 21/0217

(57) ABSTRACT

An integrated circuit with reduced gate induced drain leakage and with reduced reverse biased diode leakage is formed using a process that employs a first laser anneal, a rapid thermal anneal, and a second laser anneal after implanting the source and drain dopant to improve transistor performance.

### CROSS-REFERENCE TO RELATED APPLICATIONS

This application claims the benefit of priority under U.S.C. §119(e) of U.S. Provisional Application 61/921,508 (Texas Instruments docket number TI-71500, filed Dec. 29, 2013), the contents of which are hereby incorporated by reference.

### FIELD OF INVENTION

This invention relates to the field of integrated circuits. More particularly, this invention relates to diode leakage in an integrated circuit.

### BACKGROUND

Portable electronic devices demand long battery life. A major factor that contributes to battery lifetime is the amount of current that is consumed by the circuit during standby. During a standby mode such as when a cell phone is not being used or a laptop is not being used, voltage may be applied to transistor gates and to reverse biased diodes to preserve logic states so the device may resume operation when awakened from the standby mode. The amount of leakage current that flows during standby may have a major impact upon battery lifetime.

Two significant transistor leakage mechanisms when integrated circuits are in the standby mode are gate induced drain leakage (GIDL) and reverse biased diode leakage.

Typically when an n-type metal-oxide-semiconductor (NMOS) transistor is in a standby state, the drain of the transistor is at Vdd (power supply voltage) and the gate is at Vss (ground). This voltage is applied across the thin gate dielectric adjacent to the transistor drain. There may be sufficient bending of the energy bands near the drain at the interface between the silicon and the gate dielectric to enable valance-band electrons to tunnel into the conduction band resulting in significant GIDL current. Reducing GIDL current may significantly prolong battery life.

In addition, when an integrated circuit is in the standby mode, thousands of diodes may be reverse biased. Reverse biased diode leakage from thousands of reverse biased diodes in parallel may significantly reduce battery life. Reducing reverse biased diode leakage may significantly prolong battery life.

One method of improving NMOS transistor performance is to apply tensile stress to the NMOS transistor channel. Tensile stress enhances the mobility of the electron carriers which improves the performance of the NMOS transistors.

A stress memorization technique (SMT) in which a highly stressed SMT film is deposited over a polysilicon gate and then annealed at a high enough temperature to recrystallize the polysilicon gate is commonly used to enhance NMOS transistor performance. The tensile stress is “memorized” by the polysilicon gate during recrystallization. The tensile stress that is memorized by the polysilicon gate is then transferred to the NMOS transistor channel when the highly stressed SMT film is removed. The SMT process may increase GIDL and reverse biased diode leakage.

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

An integrated circuit with reduced gate induced drain leakage and with reduced reverse biased diode leakage is formed using a process that employs a first laser anneal, a rapid thermal anneal, and a second laser anneal after implanting the source and drain dopant to improve transistor performance.

### BRIEF DESCRIPTION OF THE DRAWINGS

FIG. 1 is an example process flow according to principles of the invention.

FIG. 2A is a cross-section of a MOS transistor describing a gated diode leakage measurement.

FIG. 2B is a graph of gated diode leakage for transistors formed according to principles of the invention and compared with gated diode leakage for transistors formed using a conventional process.

FIG. 3A is a cross-section of a MOS transistor describing a diode leakage measurement.

FIG. 3B is a graph of diode leakage for transistors formed according to principles of the invention and compared with gated diode leakage for transistors formed using a conventional process.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

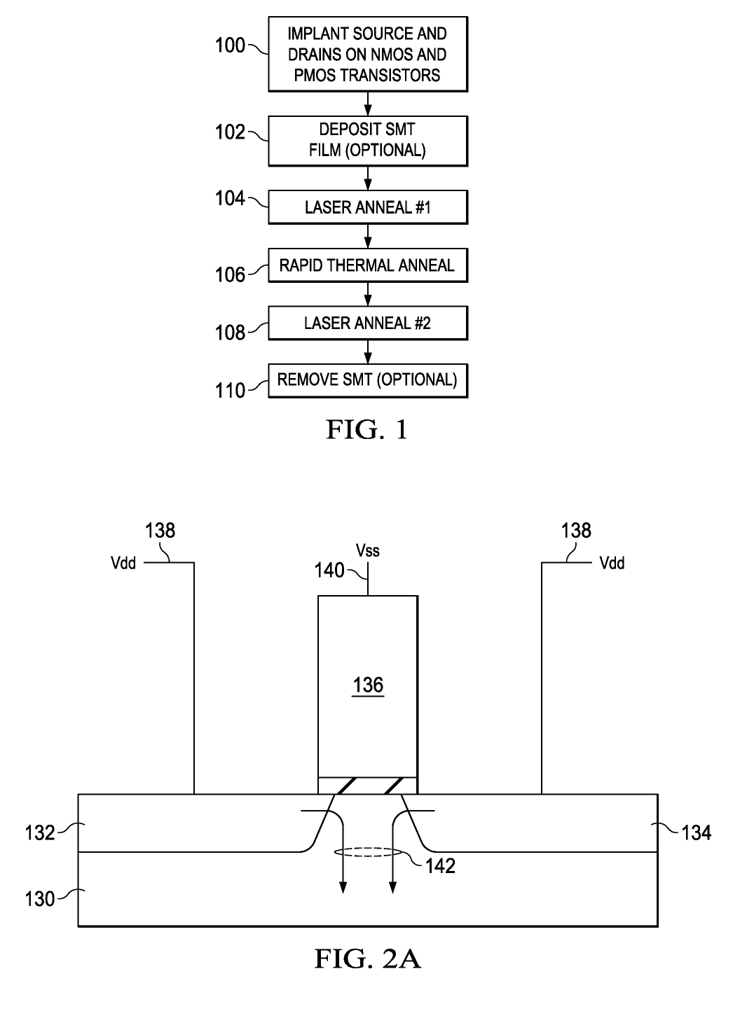

A process which unexpectedly reduces gate induced diode leakage (GIDL) and reverse biased diode leakage (RBDL) in NMOS transistors is illustrated in FIG. 1. This integrated circuit manufacturing process flow may utilize stress memorization (SMT) to enhance NMOS transistor performance

Unlike conventional process flows which typically utilize one laser anneal step (LSA) and one rapid thermal anneal (RTA) step to activate source and drain dopants, the embodiment process employs two laser anneal steps, 104 and 108 post source and drain implant 100 to enhance NMOS transistor performance. In the embodiment flow a first LSA anneal 104 is performed prior to the RTA step 106 and a second LSA anneal is performed post the RTA 106 step.

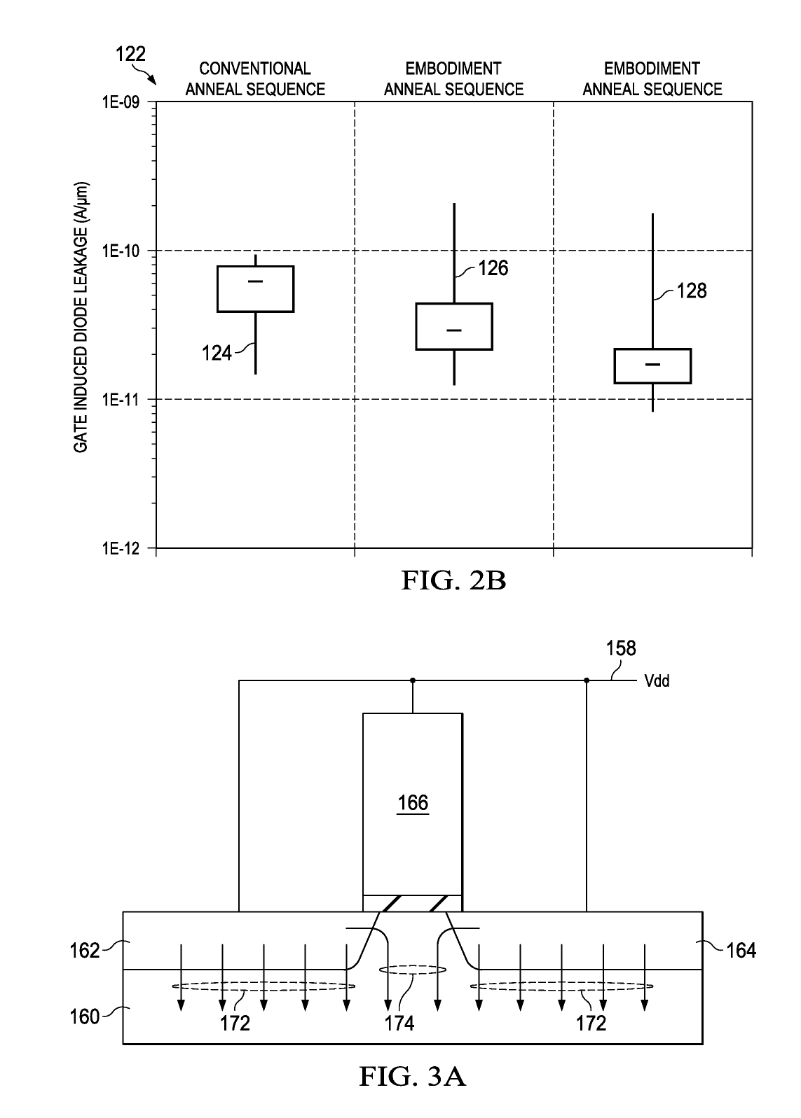

As shown in FIG. 2B, GIDL using a conventional anneal sequence is about 70 pA/um (124). GIDL (122) on a first integrated circuit lot using the embodiment anneal sequence is about 30 pA/um (126) and GIDL on a second integrated circuit lot using the embodiment anneal sequence is about 10 pA/um (128). GIDL is reduced by about 55% and 85% respectively on the two lots using the embodiment anneal sequence. The embodiment anneal sequence reduces GIDL by more than half

As shown in FIG. 2A, GIDL is measured by applying Vdd 138 to the source 132 and drain 134 and Vss 140 to the gate 136 of the NMOS transistor. The substrate 130 is grounded. The large voltage drop across the thin gate dielectric in the gate 136/drain 134 and gate 136/source 132 overlap regions can bend the energy bands sufficiently to enable the carriers to tunnel directly from the valence band to the conduction band resulting in GIDL current 142.

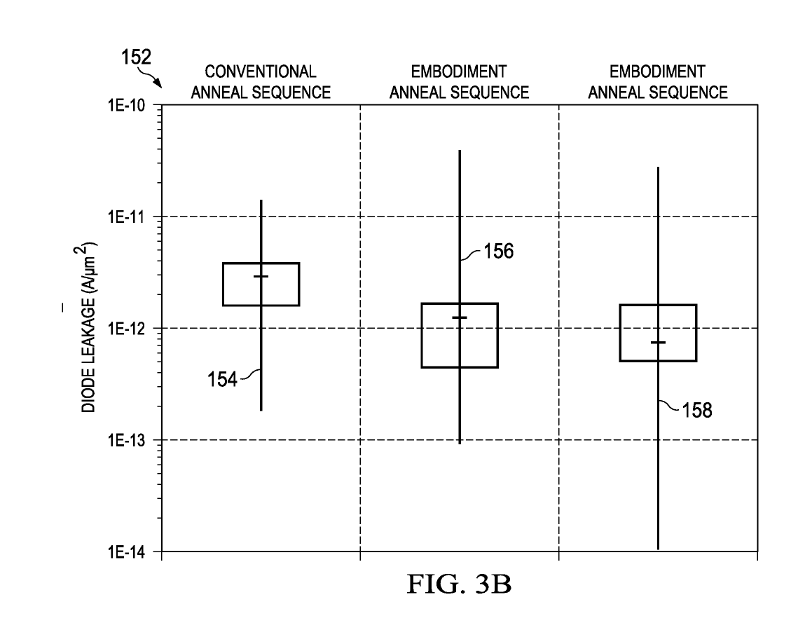

As shown in FIG. 3B, reverse biased diode leakage (RBDL) using a conventional anneal sequence is about 40 pA/um² (154). RBDL on a first integrated circuit lot using the embodiment anneal sequence is about 15 pA/um² (156) and RBDL on a second integrated circuit lot using the embodiment anneal sequence is about 0.8 pA/um² (158). RBDL is reduced by about 60% and 98% respectively on these two lots employing the embodiment anneal sequence.

As shown in FIG. 3A, RBDL is measured by applying Vdd 158 to the source 162 and drain 164 and gate 166 of the NMOS transistor. The substrate 160 is grounded. The voltage drop across the reverse biased source and drain causes a depletion region to form and causes a reverse bias diode leakage current (RBDL) 172 to flow from the bottom of the diode 162 and 164 and current 174 to also flow also from the sidewalls of the diodes 162 and 164. Defects generated during the ion implantation process may end up in the depletion region resulting in an increase in RBDL. Optimizing the source and drain anneal sequence to reduce crystal defects in the depletion region may result in a reduction in RBDL.

Reduction in GIDL and in RBDL may significantly reduce the off current and standby current of an integrated circuit and may significantly prolong battery life.

Referring again to FIG. 1 after the source and drains of polysilicon gate transistors are implanted (step 100) an SMT (stress memorization technique) film with tensile stress may be deposited over the transistors in the integrated circuit. Deposition of the SMT film is optional. It may be used to enhance the mobility of carriers in the channel of the NMOS transistor to improve NMOS transistor performance.

A first laser anneal (LSA) may then be performed as shown in step 104. The LSA may be performed in an inert ambient at a temperature in the range of 1100° C. to 1250° C. In an example embodiment the LSA is a 1150° C. anneal in an argon ambient. The LSA anneal activates dopant by replacing silicon atoms in the single crystal silicon with dopant atoms.

The first LSA anneal 104 is then followed by a rapid thermal anneal (RTA). The RTA may be performed in an inert ambient at a temperature in the range of 950° C. to 1050° C. for a time ranging from 0.1 msec to 10 sec. The time and temperature is chosen to regrow amorphous silicon produced during the ion implantation back into single crystal silicon and to heal single crystal defects. The RTA also causes dopant diffusion and is used to control the gate to drain overlap in the transistors. Some dopant that was activated by the first LSA may be deactivated during the RTA. In an example embodiment the RTA is a 1015° C. anneal performed for 1.25 sec.

A second laser anneal (LSA) may then be performed as shown in step 108. The LSA may be performed in an inert ambient at a temperature in the range of 1100° C. to 1250° C. In an example embodiment the LSA is a 1250° C. anneal in an argon ambient. This second LSA anneal may additionally activate dopant atoms.

As shown in step 110 the SMT film if present may then be removed from the integrated circuit. If the SMT film is present, the polysilicon in the NMOS transistor gate recrystallizes while the tensile SMT film is in place and memorizes the stress. After the SMT film is removed the recrystallized polysilicon NMOS transistor gate continues to apply tensile stress to the transistor channel thus boosting NMOS transistor performance.

After the embodiment anneals, in a typical integrated circuit manufacturing flow the SMT film if present is removed and the source, drains, and gates may be silicided. Layers of dielectric and interconnect may then be formed over the transistors to complete the integrated circuit.

Those skilled in the art to which this invention relates will appreciate that many other embodiments and variations are possible within the scope of the claimed invention.

What is claimed is:

1. A process of forming an integrated circuit, comprising the steps:
providing a partially processed integrated circuit wherein the partially processed integrated circuit is processed through a source and drain implant doping step and wherein the partially processed integrated circuit includes transistor gates;
performing a first laser anneal in an inert ambient with a temperature in the range of about 1100° C. to 1250° C. after the source and drain implant doping step;
performing a rapid thermal anneal in an inert ambient with a temperature in the range of about 950° C. to 1050° C. and a time in the range of about 0.1 sec to about 10 sec after the first laser anneal step; and
performing a second laser anneal in an inert ambient with a temperature in the range of about 1100° C. to 1250° C. after the step of performing a rapid thermal anneal.

2. The process of step 1, wherein the temperature of the first laser anneal is 1150° C., the temperature of the rapid thermal anneal is 1015° C., the time of the rapid thermal anneal is 1.25 sec, and the temperature of the second laser anneal 1250° C.

3. The process of step 1, wherein the inert ambient is argon.

4. The process of claim 1 further comprising the steps:
after the source and drain doping step and prior to the first laser anneal step, depositing a stress memorization film over the transistor gates; and
after the second laser anneal step, removing the stress memorization film.

5. The process of claim 4, wherein the stress memorization film is silicon nitride wherein the silicon nitride has tensile stress.

6. The process of claim 1, further comprising forming a silicide on the transistor gates after the first laser anneal, the rapid thermal anneal and the second laser anneal.

7. A process of forming an integrated circuit, comprising the steps:
providing a partially processed integrated circuit wherein the partially processed integrated circuit is processed through a source and drain implant doping step and wherein the partially processed integrated circuit includes polysilicon gates;
performing a first laser anneal in argon with a temperature of 1150° C. after the source and drain implant doping step;
performing a rapid thermal anneal in argon with a temperature of 1015° C. in argon and a time in the range of 1.25 sec after the first laser anneal step; and
performing a second laser anneal in argon with a temperature of 1250° C. after the step of performing a rapid thermal anneal.

8. The process of claim 7 further comprising the steps:
after the source and drain doping step and prior to the first laser anneal step, depositing a silicon nitride film with tensile stress over the polysilicon gates; and
after the second laser anneal step, removing the stress memorization film.

9. The process of claim 8, further comprising the step of forming a silicide on the polysilicon gates after the first laser anneal, the rapid thermal anneal, the second laser anneal, and removing the stress memorization film.

10. The process of claim 7, further comprising the step of forming a silicide on the polysilicon gates after the first laser anneal, the rapid thermal anneal and the second laser anneal.

11. A process of forming an integrated circuit, comprising the steps:
providing a partially processed integrated circuit wherein the partially processed integrated circuit is processed through a source and drain implant doping step and wherein the partially processed integrated circuit includes transistor gates;
depositing a silicon nitride stress memorization layer with tensile stress on the integrated circuit;
performing a first laser anneal in an inert ambient with a temperature in the range of about 1100° C. to 1250° C. after the source and drain implant doping step;
performing a rapid thermal anneal in an inert ambient with a temperature in the range of about 950° C. to 1050° C. and a time in the range of about 0.1 sec to about 10 sec after the first laser anneal step;
performing a second laser anneal in an inert ambient with a temperature in the range of about 1100° C. to 1250° C. after the step of performing a rapid thermal anneal; and
then, removing the silicon nitride stress memorization layer.
